(19) United States
(12) Patent Application Publication
(10) Pub. No.: US 2025/0031447 A1
(43) Pub. Date: Jan. 23, 2025

(54) Display Substrate, Display Panel and Display Device

(71) Applicant: BOE Technology Group Co., Ltd., Beijing (CN)

(72) Inventors: Zhengliang LI, Beijing (CN); Guangcai YUAN, Beijing (CN); Ce NING, Beijing (CN); Zhonghao HUANG, Beijing (CN); Zhixiang ZOU, Beijing (CN); Zhangtao WANG, Beijing (CN); Jie HUANG, Beijing (CN); Nianqi YAO, Beijing (CN); Jiayu HE, Beijing (CN); Hehe HU, Beijing (CN); Feifei LI, Beijing (CN); Kun ZHAO, Beijing (CN); Chen XU, Beijing (CN); Hui GUO, Beijing (CN)

(21) Appl. No.: 18/279,205

(22) PCT Filed: Oct. 31, 2022
(86) PCT No.: PCT/CN2022/128741

§ 371 Date: Aug. 28, 2023

(51) Int. Cl. H01L 27/12; H01L 23/00

(52) U.S. Cl. CPC H01L 27/124; H01L 23/564

(57) ABSTRACT

A display substrate, including: a base substrate; and a metal conductive layer, located at a side of the base substrate, and including a core conductive layer and a functional conductive layer laminated along a direction away from the base substrate; a material of the core conductive layer includes a conductive metal material; a material of the functional conductive layer includes a first diffusion barrier metal material and a first adhesion force enhancing metal material, wherein the first diffusion barrier metal material is configured to block diffusion of the conductive metal material, and the first adhesion force enhancing metal material is configured to enhance an adhesion force between the functional conductive layer and a photoresist used in a patterning process of the functional conductive layer; a surface energy of any of first adhesion force enhancing metal materials is less than or equal to 325 mJ/m².

### CROSS-REFERENCE TO RELATED APPLICATION

The present disclosure is a U.S. National Phase Entry of International Application PCT/CN2022/128741 having an international filing date of Oct. 31, 2022, and the contents disclosed in the above-mentioned application are hereby incorporated herein by reference.

### TECHNICAL FIELD

The present invention relates to the field of display, in particular to a display substrate, a display panel, and a display device.

### BACKGROUND

In the field of display technologies, with an increasing popularity of large-size and high-resolution display products, low-resistance copper (Cu) wiring technology has attracted more and more attention. However, because of easy diffusion characteristics of copper, when copper diffuses to another film layer, performance of the whole product will be adversely affected.

### SUMMARY

The present invention aims at solving at least one of technical problems existing in the prior art, and provides a display substrate, a display panel, and a display device.

In a first aspect, an embodiment of the present disclosure provides a display substrate, including a base substrate; and a metal conductive layer, located at a side of the base substrate, the metal conductive layer including a core conductive layer and a functional conductive layer that are stacked along a direction away from the base substrate; a material of the core conductive layer includes a conductive metal material; a material of the functional conductive layer includes a first diffusion barrier metal material and at least one first adhesion force enhancing metal material, wherein the first diffusion barrier metal material is configured to block diffusion of the conductive metal material, and the at least one first adhesion force enhancing metal material is configured to enhance an adhesion force between the functional conductive layer and a photoresist used in a patterning process of the functional conductive layer; a surface energy of any of the at least one first adhesion force enhancing metal material is less than or equal to 325 mJ/m², and a range of a sum of atomic percents of all of the at least one first adhesion force enhancing metal material in the functional conductive layer is 5% to 60%.

In some embodiments, the material of the functional conductive layer further includes a first oxidation resistance metal material configured to enhance an oxidation resistance performance of the functional conductive layer; and a sum of atomic percents of the first oxidation resistance metal materials in the functional conductive layer is 5% to 30%.

In some embodiments, the first oxidation resistance metal material includes nickel.

In some embodiments, the at least one first adhesion force enhancing metal material in the functional conductive layer includes: at least one of aluminum, silver, gold, barium, bismuth, cadmium, cerium, chromium, titanium, gallium, germanium, indium, manganese, neodymium, palladium, platinum, rubidium, antimony, scandium, tin, strontium, yttrium, zinc, and zirconium.

In some embodiments, the first diffusion barrier metal material and the conductive metal material are configured such that they are able to be etched using a same etching liquid.

In some embodiments, the conductive metal material includes copper, and the first diffusion barrier metal material includes molybdenum.

In some embodiments, a range of atomic percents of the first diffusion barrier metal material in the functional conductive layer is 40% to 90%.

In some embodiments, the metal conductive layer further includes a buffer conductive layer located at a side of the core conductive layer away from the functional conductive layer and in contact with the core conductive layer; and a material of the buffer conductive layer includes a second diffusion barrier metal material, configured to block diffusion of the conductive metal material.

In some embodiments, the second diffusion barrier metal material includes molybdenum.

In some embodiments, the material of the buffer conductive layer further includes at least one second adhesion force enhancing metal material, configured to enhance an adhesion force between the buffer conductive layer and the core conductive layer.

In some embodiments, a surface energy of any of the at least one second adhesion force enhancing metal material is less than or equal to 325 mJ/m², and a range of a sum of atomic percents of all of the at least one second adhesion force enhancing metal material in the functional conductive layer is 5% to 60%.

In some embodiments, the second adhesion force enhancing metal material in the buffer conductive layer includes: at least one of aluminum, silver, gold, barium, bismuth, cadmium, cerium, chromium, titanium, gallium, germanium, indium, manganese, neodymium, palladium, platinum, rubidium, antimony, scandium, tin, strontium, yttrium, zinc, and zirconium.

In some embodiments, the material of the buffer conductive layer further includes: a second oxidation resistance metal material, configured to enhance an oxidation resistance performance of the buffer conductive layer; and a sum of atomic percents of the second oxidation resistance metal material in the buffer conductive layer is 5% to 30%.

In some embodiments, the first oxidation resistance metal material includes nickel.

In some embodiments, the second diffusion barrier metal material includes molybdenum; and a range of atomic percents of the second diffusion barrier metal material in the buffer conductive layer is 40% to 90%.

In some embodiments, the material of the buffer conductive layer and the material of the functional conductive layer are the same.

In some embodiments, a thickness of the buffer conductive layer is 50 Å to 600 Å.

In some embodiments, a thickness of the core conductive layer is 1000 Å to 6000 Å, and a thickness of the functional conductive layer is 50 Å to 600 Å.

In some embodiments, the metal conductive layer includes multiple conductive patterns, and a range of a sidewall slope angle of the conductive patterns is 40° to 50°.

In some embodiments, the display substrate includes: a first conductive layer which is located at a side of the base substrate and including a gate line; a first insulation layer located at a side of the first conductive layer away from the base substrate; a second conductive layer which is located at a side of the first insulation layer away from the base substrate and including a data line; and at least one of the first conductive layer and the second conductive layer is the metal conductive layer.

In a second aspect, an embodiment of the present disclosure further provides a display panel, wherein the display panel includes: the display substrate as provided in the above first aspect and an opposite substrate disposed opposite to the display substrate.

In a third aspect, an embodiment of the present disclosure further provides a display device, wherein the display device includes the display panel as provided in the above second aspect.

### BRIEF DESCRIPTION OF DRAWINGS

FIG. 1 is a schematic diagram of an appearance of disconnection defect in the related art.

FIG. 2 is a schematic cross-sectional view along a direction of A-A′ in FIG. 1.

FIG. 3A is a schematic cross-sectional view of a partial region of a display substrate according to an embodiment of the present disclosure.

FIG. 3B is a schematic cross-sectional view of a partial region of a display substrate according to an embodiment of the present disclosure.

FIG. 4 is a schematic cross-sectional view of a metal conductive layer in an embodiment of the present disclosure.

FIG. 5 is a schematic diagram of comparison between a defective rate of disconnection defect appearing in a metal conductive layer in the related art and that in a metal conductive layer in an embodiment of the present disclosure.

FIG. 6 is a schematic diagram of comparison between an oxidation resistance effect of a diffusion barrier conductive layer in the related art with that of a functional conductive layer in an embodiment of the present disclosure.

FIG. 7 is another schematic cross-sectional view of a metal conductive layer in an embodiment of the present disclosure.

FIG. 8 is electron microscope scan views at sidewalls of conductive patterns obtained by a metal conductive layer after completing patterning in the related art and a metal conductive layer after completing patterning in the present disclosure.

### DETAILED DESCRIPTION

A display substrate, a display panel, and a display device according to the present invention are described in detail below with reference to the accompanying drawings to enable those skilled in the art to better understand technical solutions of the present invention.

“First”, “second”, and similar terms used in the embodiments of the present disclosure do not represent any order, quantity, or importance, but are only used for distinguishing different components. Likewise, “include”, “contain”, or a similar term means that an element or an object appearing before the term covers an element or an object listed after the term and its equivalent, but does not exclude other elements or objects. “Couple”, “join”, or a similar term is not limited to physical or mechanical coupling, but may include electrical coupling (that is, an electrical connection), no matter the coupling is direct or indirect.

As described in embodiments of the present disclosure, A structure is located at a side of B structure away from a base substrate, which refers that for a region in which orthographic projections of the two structures A and B overlap on the base substrate, a distance between the base substrate and a part of the A structure in the region where the orthographic projections overlap is greater than a distance the base substrate and between a part of the B structure in the region where the orthographic projections overlap. In terms of preparing procedures, a preparing procedure of a material thin film for forming the A structure may be performed following a preparing procedure of a material thin film for forming the B structure.

“About” or “approximately” as used in embodiments of the present disclosure includes a stated value and means being within an acceptable range of deviations for specific values as determined by those of ordinary skills in the art in consideration of measurements in question and errors associated with measurements of specific quantities (that is, limitations of a measurement system). For example, “about” may mean that a difference from the stated value is within one or more standard deviations, or within a range of ±30%, 20%, 10%, 5%.

In addition, in an expression of a range M to N in the embodiments of the present disclosure, a defined range includes two endpoint values M and N.

In the related art, considering a characteristic of low resistivity of copper, a conductive layer including conductive wirings will be prepared using copper. However, copper has easy diffusion characteristics, and after copper diffuses to another film layer, performance of a whole product will be adversely affected. For example, when a first conductive layer in which a gate line and a gate are located is prepared by copper, the copper in the first conductive layer will diffuse to a gate insulation layer or even to an active layer. When a second conductive layer in which a data line and a source and a drain are located is prepared by copper, the copper in the second conductive layer will diffuse to a passivation layer located above the second conductive layer. The problem of copper diffusion appearing in the first conductive layer/second conductive layer will affect characteristics of a channel region in the active layer.

In order to effectively improve the problem of copper diffusion, a conductive layer uses a double-layer metal structure of copper+diffusion barrier conductive layer, in which the diffusion barrier conductive layer is located at a side of the copper away from the base substrate, and a relatively good geothermal stability material is generally selected as a material of the diffusion barrier conductive layer to block copper diffusion. At present, molybdenum (Mo) is generally selected as a material of a barrier conductive film.

A process for preparing the conductive layer with the double-layer metal structure is roughly as follows: firstly, a copper film with a certain thickness is formed; then, a molybdenum film is formed above the copper film; then, photoresist is coated on the molybdenum film; then, the photoresist is exposed and developed to perform optical composition on the photoresist first; then, the copper film and the molybdenum film are etched based on the photoresist after the optical composition to pattern the copper film and the molybdenum film; finally, the photoresist is peeled off.

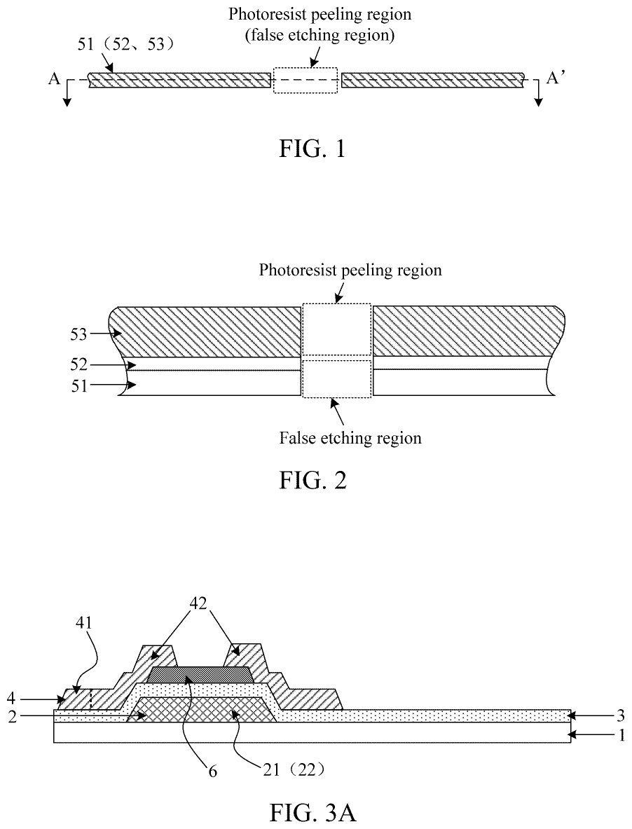

FIG. 1 is a schematic diagram of appearance of disconnection defect in the related art. FIG. 2 is a schematic cross-sectional view along a direction of A-A′ in FIG. 1. As shown in FIGS. 1 and 2, in the related art, since an adhesion force between a photoresist 53 and a molybdenum film 52 (that is, a diffusion barrier conductive layer) is relatively poor, after the photoresist 53 is exposed and developed, the photoresist 53 located in a region in which a conductive pattern is to be formed subsequently is retained, while the photoresist 53 in other regions is removed. At this time, the photoresist located in a region in which a conductive pattern of a small size or a narrow line width is to be formed subsequently (for example, the gate line, the gate in the aforementioned first conductive layer, the data line, the source and the drain in the second conductive layer) also has a feature of small size or narrow line width, and an adhesion force between the photoresist 53 with narrow line width and the molybdenum film 52 is even worse. In a subsequent process for etching the copper film 51 and the molybdenum film 52 based on the photoresist 53 after the optical composition, an etching liquid will have a large impact on the photoresist 53, and the photoresist 53 with small size and narrow line width is extremely prone to peeling, thereby leading to false etching, and then disconnection and other defects will appear.

In order to effectively improve or even completely solve at least one of technical problems existing in the related art, an embodiment of the present disclosure provides a display substrate. Hereinafter, technical solutions in the embodiments of the present disclosure will be described in detail with reference to the accompanying drawings.

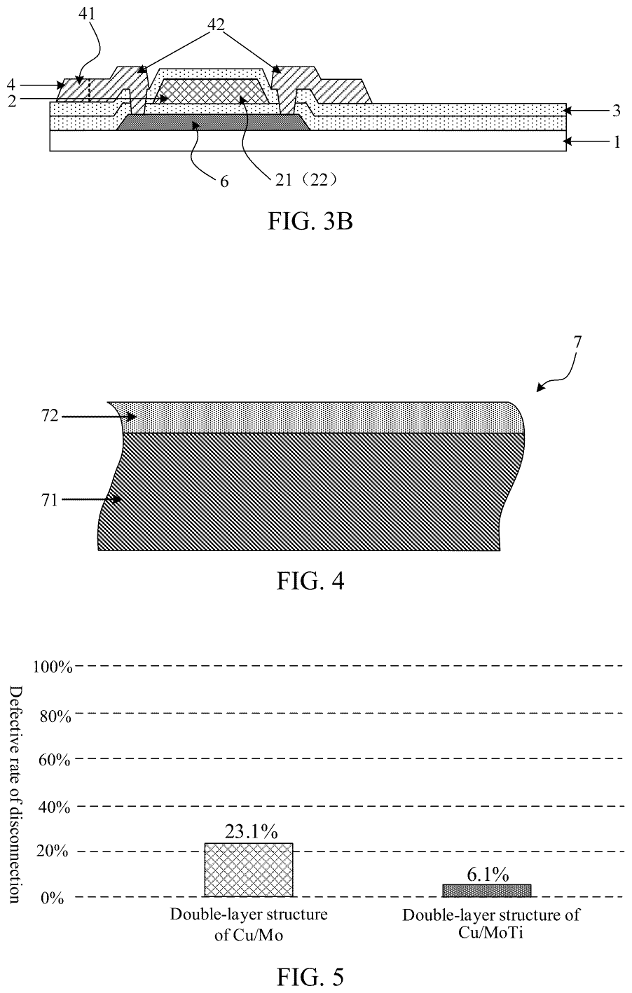

FIG. 3A is a schematic cross-sectional view of a partial region of a display substrate according to an embodiment of the present disclosure. FIG. 3B is a schematic cross-sectional view of a partial region of a display substrate according to an embodiment of the present disclosure. FIG. 4 is a schematic cross-sectional view of a metal conductive layer in an embodiment of the present disclosure. As shown in FIGS. 3A to 4, the display substrate includes: a base substrate 1 and a metal conductive layer 7.

Among them, a base substrate 11 may be a flexible base substrate 1 (e.g. resin base substrate 1) or a rigid base substrate 1 (e.g. glass base substrate 1).

The metal conductive layer 7 is located at a side of the base substrate 1, and the metal conductive layer 7 includes a core conductive layer 71 and a functional conductive layer 72 stacked in a direction away from the base substrate 1. A material of the core conductive layer 71 includes a conductive metal material, and a material of the functional conductive layer 72 includes a first diffusion barrier metal material and a first adhesion force enhancing metal material. The first diffusion barrier metal material is configured to block diffusion of the conductive metal material, and the first adhesion force enhancing metal material is configured to enhance an adhesion force between the functional conductive layer 72 and a photoresist in a patterning process of the functional conductive layer 72. A surface energy of any of first adhesion force enhancing metal materials is less than or equal to 325 mJ/m², and a range of a sum of atomic percents of all first adhesion force enhancing metal materials in the functional conductive layer 72 is 5% to 60%.

In the embodiment of the present disclosure, the functional conductive layer 72 is disposed on the core conductive layer 71, the material of the functional conductive layer 72 includes the first diffusion barrier metal material and the first adhesion force enhancing metal material, wherein the first diffusion barrier metal material may be used for blocking diffusion of the conductive metal material in the core conductive layer 71, and the first adhesion force enhancing metal material may be used for improving and enhancing an adhesion force between the functional conductive layer 72 and the photoresist used in the patterning process of the functional conductive layer 72, so that the photoresist with small size and narrow line width can all retain a relatively strong adhesion force with the lower functional conductive layer 72 after the optical composition of the photoresist is completed, and the photoresist can be effectively prevented from peeling when the functional conductive layer 72 is subsequently etched by using an etching liquid, and thus false etching can be avoided, and then a defect problems such as wire disconnection or the like can be improved.

In an embodiment of the present disclosure, by adding the first adhesion force enhancing metal material in the functional conductive layer 72, a contact angle between the photoresist coated in the patterning process of the functional conductive layer 72 and the functional conductive layer 72 (an included angle from a solid-liquid interface passing through the inside of the liquid to a gas-liquid interface at a junction of solid, liquid, and gas phases) may be increased.

According to Young's equation (also called wetting equation):

$${γ}_{sv} - {γ}_{SL} = {γ}_{Lv} * COS θ$$

γₛᵥ, γ_{SL}, γ_{Lv} represent solid-gas interface tensile force, solid-liquid interface tensile force, and liquid-gas interface tensile force respectively, and θ represents a solid-liquid contact angle; among them, the smaller a solid surface energy (has a positive correlation with the solid-gas interfacial tensile force γₛᵥ), the larger the solid-liquid contact angle, the stronger lipophobicity of a solid surface, and the stronger the adhesion force between solid and liquid. For example, a surface energy of molybdenum is about 464 mJ/m², a contact angle between a molybdenum film and a photoresist is about 12°; a surface energy of titanium (Ti) is about 207 mJ/m², and a contact angle between a titanium film and a photoresist is about 39°.

Based on the above principle, a surface energy of the first adhesion force enhancing metal material selected in an embodiment of the present disclosure is smaller than a surface energy of the first diffusion barrier metal material, so that a surface energy of the functional conductive layer 72 can be reduced, so that an adhesion force between the photoresist and a surface of the functional conductive layer 72 is increased.

In some embodiments, the first diffusion barrier metal material and the conductive metal material are configured such that they may be etched using a same etching liquid. At this time, the core conductive layer 71 and the functional conductive layer 72 may be etched using the same etching liquid at one time, which is beneficial to reducing a quantity of etching processes.

In some embodiments, the conductive metal material includes: copper, and the first diffusion barrier metal material includes: molybdenum (Mo, with a surface energy of about 464 mJ/m²). At this time, the core conductive layer 71 and the functional conductive layer 72 may be etched using a hydrogen peroxide-based copper etching liquid (a concentration of the etching liquid may be preset as required).

In an embodiment of the present disclosure, in a case where an atomic percent of the first adhesion force enhancing metal material is fixed, the smaller the surface energy of the selected first adhesion force enhancing metal material, the stronger the adhesion force between the functional conductive layer 72 and the photoresist, and the larger the surface energy of the selected first adhesion force enhancing metal material, the weaker the adhesion force between the functional conductive layer 72 and the photoresist. In addition, in a case where the selected first adhesion force enhancing metal material is fixed, the larger the sum of the atomic percents of all the first adhesion force enhancing metal materials in the functional conductive layer 72, the stronger the adhesion force between the functional conductive layer 72 and the photoresist, and the smaller the sum of the atomic percents of all the first adhesion force enhancing metal materials in the functional conductive layer 72, the weaker the adhesion force between the functional conductive layer 72 and the photoresist. However, the larger the sum of the atomic percents of the first adhesion force enhancing metal materials, the smaller an atomic percent of the first diffusion barrier metal material in the functional conductive layer 72, at which time the weaker a diffusion-blocking effect of the functional conductive layer 72 on the conductive metal material in the core conductive layer 71.

In some embodiments, both factors of a blocking effect on the conductive metal material and the adhesion force with the photoresist are taken into account, the surface energy of any of the first adhesion force enhancing metal materials is less than or equal to 325 mJ/m², a range of the sum of the atomic percents of all the first adhesion force enhancing metal materials in the functional conductive layer 72 is 5% to 60%, and a range of atomic percents of first diffusion barrier metal materials in the functional conductive layer 72 is 40% to 90%. With the above configuration, the functional conductive layer 72 can not only effectively block diffusion of the conductive metal material, but also effectively improve the adhesion between the functional conductive layer 72 and the photoresist, and thus a problem of photoresist peeling can be effectively improved.

In some embodiments, the first adhesion force enhancing metal material in the functional conductive layer 72 includes: at least one of aluminum (Al, with a surface energy of about 155 mJ/m²), silver (Ag, with a surface energy of about 159 mJ/m²), gold (Au, with a surface energy of about 177 mJ/m²), barium (Ba, with a surface energy of about 44 mJ/m²), bismuth (Bi, with a surface energy of about 69 mJ/m²), cadmium (Cd, with a surface energy of about 73 mJ/m²), cerium (Ce, with a surface energy of about 50 mJ/m²), chromium (Cr, with a surface energy of about 293 mJ/m²), titanium (Ti, with a surface energy of about 207 mJ/m²), gallium (Ga, with a surface energy of about 58 mJ/m²), germanium (Ge, with a surface energy of about 286 mJ/m²), indium (In, with a surface energy of about 34 mJ/m²), manganese (Mn, with a surface energy of about 206 mJ/m²), neodymium (Nd, with a surface energy of about 65 mJ/m²), palladium (Pd, with a surface energy of about 272 mJ/m²), platinum (Pt, with a surface energy of about 299 mJ/m²), rubidium (Rb, with a surface energy of about 10 mJ/m²), antimony (Sb, with a surface energy of about 134 mJ/m²), scandium (Sc, with a surface energy of about 150 mJ/m²), tin (Sn, with a surface energy of about 62 mJ/m²), strontium (Sr, with a surface energy of about 52 mJ/m²), yttrium (Y, with a surface energy of about 100 mJ/m²), zinc (Zn, with a surface energy of about 110 mJ/m²), zirconium (Zr, with a surface energy of about 187 mJ/m²).

FIG. 5 is a schematic diagram of comparison between a defective rate of disconnection defects appearing in a metal conductive layer in the related art with that in a metal conductive layer in an embodiment of the present disclosure. As shown in FIG. 5, in the related art, the metal conductive layer has a double-layer structure of Cu/Mo, and a defective rate of disconnection defects appearing in the metal conductive layer (a ratio of a quantity of substrates with an appearance of disconnection defects to a total quantity of total substrates) after completion of etching is about 23.1%. In an embodiment of the present disclosure, the metal conductive layer uses a double-layer structure of Cu/MoTi, and the defective rate of disconnection defects appearing in the metal conductive layer after completion of etching is about 6.1%. It can be seen that the technical solutions of the present disclosure can effectively reduce a defective rate of disconnection.

In a practical application, a metal material with a relatively small resistivity is generally selected as the conductive metal material in the core conductive layer 71, and these metal materials (for example, copper) often have a characteristic of being prone to oxidation. The oxidation of the conductive metal material will increase an overall resistance of the core conductive layer 71, and at the same time will reduce an adhesion force between the core conductive layer 71 and an adjacent film layer (subsequently defects such as bubbling and film layer peeling are prone to appearing).

In order to effectively improve the above technical problems, in an embodiment of the present disclosure, the material of the functional conductive layer 72 includes not only the first diffusion barrier metal material and the first adhesion force enhancing metal material described above, but also a first oxidation resistance metal material, which is configured to enhance an oxidation resistance performance of the functional conductive layer 72. A sum of atomic percents of first oxidation resistance metal materials in the functional conductive layer 72 is 5% to 30%.

In some embodiments, the first oxidation resistance metal material includes: nickel (Ni). Nickel has a relatively good oxidation resistance performance.

With the above arrangement, the functional conductive layer 72 can not only effectively block diffusion of the conductive metal material in the core conductive layer 71, but also effectively improve the adhesion force between the functional conductive layer 72 and the photoresist, and at the same time, can effectively prevent the conductive metal material in the core conductive layer 71 from being oxidized.

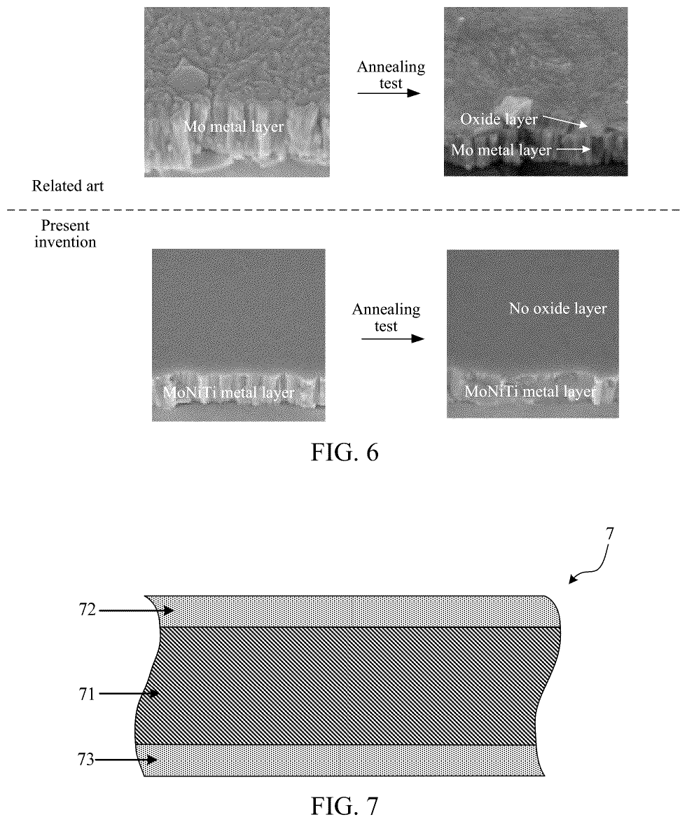

FIG. 6 is a schematic diagram of comparison between an oxidation resistance effect of a diffusion barrier conductive layer in the related art with that of a functional conductive layer in an embodiment of the present disclosure. As shown in FIG. 6, as an example, the material of the diffusion barrier conductive layer in the related art is Mo and has a thickness of 200 nm. A material of the functional conductive layer 72 in the present disclosure is a MoNiTi alloy and has a thickness of 200 nm. After an annealing test in an air atmosphere of 350° C. for one hour, Mo on a surface of the diffusion barrier conductive layer in the related art is obviously oxidized to form an oxide layer, and no oxide layer appears on a surface of the functional conductive layer 72 in the present disclosure. It can be seen that oxidation resistance performance of the functional conductive layer 72 in the embodiment of the present disclosure is better.

It should be noted that when the material of the diffusion barrier conductive layer in the related art is Mo, a contact angle of a photoresist on the surface of the diffusion barrier conductive layer is about 11.68°. When the material of the functional conductive layer 72 is an MoNiTi alloy, a contact angle of a photoresist on the surface of the functional conductive layer 72 is about 33.43°. Therefore, a bonding force between the functional conductive layer 72 formed by the MoNiTi and the photoresist alloy in the present disclosure is greater than a bonding force between an MoNiTi alloy formed by Mo metal and the photoresist in the related art.

FIG. 7 is another schematic cross-sectional view of a metal conductive layer in an embodiment of the present disclosure. As shown in FIG. 7, the metal conductive layer 7 shown in FIG. 7 includes not only the core conductive layer 71 and the functional conductive layer 72, but also a buffer conductive layer 73. The buffer conductive layer 73 is located at a side of the core conductive layer 71 away from the functional conductive layer 72 and in contact with the core conductive layer 71.

In some embodiments, a material of the buffer conductive layer 73 includes a second diffusion barrier metal material, which is configured to block diffusion of a conductive metal material.

In an embodiment of the present disclosure, the first diffusion barrier metal material in the functional conductive layer 72 can effectively block upward diffusion of the conductive metal material in the core conductive layer 71, while the second diffusion barrier metal material in the buffer conductive layer 73 can effectively block downward diffusion of the conductive metal material in the core conductive layer 71.

In some embodiments, the second diffusion barrier metal material and the conductive metal material are configured such that they may be etched using a same etching liquid.

In some embodiments, the second diffusion barrier metal material is the same as the first diffusion barrier metal material.

In some embodiments, the conductive metal material includes copper, and the first diffusion barrier metal material includes molybdenum. The second diffusion barrier metal material includes molybdenum.

In some embodiments, the material of the buffer conductive layer 73 further includes a second adhesion force enhancing metal material, which is configured to enhance an adhesion force between the buffer conductive layer 73 and the core conductive layer 71.

In the embodiment of the present disclosure, the second adhesion force enhancing metal material is provided in the buffer conductive layer 73, so that the adhesion force between the buffer conductive layer 73 and the core conductive layer 71 is enhanced to prevent the core conductive layer 71 from peeling off a surface of the buffer conductive layer 73, which can effectively reduce a risk of disconnection.

In some embodiments, a surface energy of any of second adhesion force enhancing metal materials is less than or equal to 325 mJ/m², and a range of a sum of atomic percents of all second adhesion force enhancing metal materials in the functional conductive layer 72 is 5% to 60%.

The second adhesion force enhancing metal material in the buffer conductive layer 73 includes: at least one of aluminum (Al, with a surface energy of about 155 mJ/m²), silver (Ag, with a surface energy of about 159 mJ/m²), gold (Au, with a surface energy of about 177 mJ/m²), barium (Ba, with a surface energy of about 44 mJ/m²), bismuth (Bi, with a surface energy of about 69 mJ/m²), cadmium (Cd, with a surface energy of about 73 mJ/m²), cerium (Ce, with a surface energy of about 50 mJ/m²), chromium (Cr, with a surface energy of about 293 mJ/m²), titanium (Ti, with a surface energy of about 207 mJ/m²), gallium (Ga, with a surface energy of about 58 mJ/m²), germanium (Ge, with a surface energy of about 286 mJ/m²), indium (In, with a surface energy of about 34 mJ/m²), manganese (Mn, with a surface energy of about 206 mJ/m²), neodymium (Nd, with a surface energy of about 65 mJ/m²), palladium (Pd, with a surface energy of about 272 mJ/m²), platinum (Pt, with a surface energy of about 299 mJ/m²), rubidium (Rb, with a surface energy of about 10 mJ/m²), antimony (Sb, with a surface energy of about 134 mJ/m²), scandium (Sc, with a surface energy of about 150 mJ/m²), tin (Sn, with a surface energy of about 62 mJ/m²), strontium (Sr, with a surface energy of about 52 mJ/m²), yttrium (Y, with a surface energy of about 100 mJ/m²), zinc (Zn, with a surface energy of about 110 mJ/m²), zirconium (Zr, with a surface energy of about 187 mJ/m²).

In some embodiments, the material of the buffer conductive layer 73 further includes a second oxidation resistance metal material, which is configured to enhance an oxidation resistance performance of the buffer conductive layer 73. A sum of atomic percents of second oxidation resistance metal materials in the buffer conductive layer 73 is 5% to 30%. In some embodiments, the second oxidation resistance metal material includes: nickel.

In an embodiment of the present disclosure, when the functional conductive layer 72 includes the first oxidation resistance metal material and the buffer conductive layer 73 includes the second oxidation resistance metal material, the functional conductive layer 72 and the buffer conductive layer 73 may provide oxidation prevention protection on the core conductive layer 71 from upper and lower sides.

In some embodiments, the second diffusion barrier metal material includes molybdenum. A range of atomic percent of the second diffusion barrier metal material in the buffer conductive layer 73 is 40% to 90%.

In some embodiments, the buffer conductive layer 73 is made of a same material as the functional conductive layer 72. Further optionally, in a case where the buffer conductive layer 73 is made of a same material as the functional conductive layer 72, atomic percents of a same metal material in the buffer conductive layer 73 and in the functional conductive layer 72 are also the same. At this time, a material thin film of the buffer conductive layer 73 and a material thin film of the functional conductive layer 72 may be deposited based on a same target material, which facilitates preparation.

Referring to FIG. 7, in some embodiments, a thickness of the buffer conductive layer 73 is 50 Å to 600 Å.

Of course, the buffer conductive layer in the embodiment of the present disclosure is not limited to a metal or alloy material, and may also be prepared by using some metal oxide materials with a relatively good conductive function. The metal oxides included in the buffer conductive layer include indium tin oxide (ITO), indium zinc oxide (IZO), and the like. The metal oxide materials can effectively block diffusion of conductive metal materials and have a relatively good oxidation resistance performance.

Referring to FIGS. 4 and 7, in some embodiments, a thickness of the core conductive layer 71 is 1000 Å to 6000 Å, and a thickness of the functional conductive layer 72 is 50 Å to 600 Å.

In a practical application, materials and thicknesses of the core conductive layer 71, the functional conductive layer 72, and the buffer conductive layer 73 may be selected according to actual needs, which are not limited in the present disclosure.

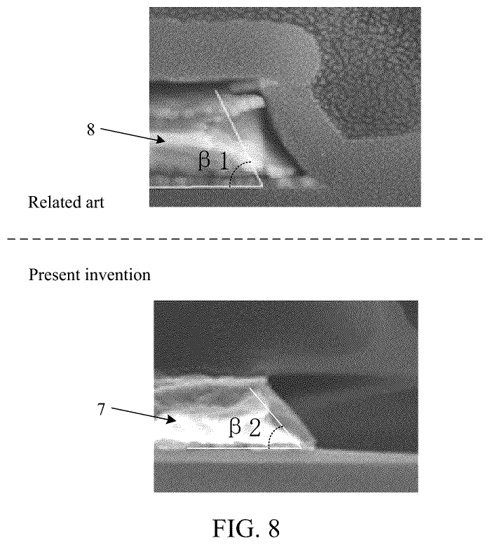

FIG. 8 is electron microscope scan views at sidewalls of conductive patterns obtained by a metal conductive layer after completing patterning in the related art and a metal conductive layer after completing patterning in the present disclosure. As shown in FIG. 8, it is found by the electron microscope scan views that a sidewall slope angle β1 of a conductive pattern obtained by the metal conductive layer 8 after completion of patterning in the related art is ≥55°, and a sidewall slope angle β2 of a conductive pattern obtained by the metal conductive layer 7 after completion of patterning in the present disclosure is 40° to 50°. Compared with the related art, the technical solution of the present disclosure can reduce the sidewall slope angle of the conductive pattern obtained by the metal conductive layer 7 after completion of patterning.

In an actual product, after patterning of the metal conductive layer 7 is completed, an insulation layer with a relatively small thickness (a material of which is generally a material of silicon oxide and/or silicon nitride) will often be formed above the metal conductive layer 7, wherein the insulation layer will form climbing at a sidewall of the conductive pattern in the metal conductive layer 7; wherein, the larger the sidewall slope angle, the more difficult it is for the insulation layer to adhere to the sidewall of the conductive pattern, and the greater the risk of the insulation layer peeling off at the sidewall, that is, the greater the risk of the sidewall of the conductive pattern being exposed, the higher a defective rate of the product. Therefore, properly reducing the sidewall slope angle of conductive pattern may effectively reduce the defective rate of the product.

Continuing referring to FIGS. 3A and 3B, in some embodiments, the display substrate includes a first conductive layer 2 (also commonly referred to as a gate layer), a first insulation layer 3, a second conductive layer 4 (also commonly referred to as an SD layer). The first conductive layer 2 is located at a side of the base substrate 1, and the first conductive layer 2 includes a gate line 21, and a gate 22 of a thin film transistor. The first insulation layer 3 is located at a side of the first conductive layer 2 away from the base substrate 1. The second conductive layer 4 is located at a side of the first insulation layer 3 away from the base substrate 1, and the second conductive layer 4 includes a data line 41 and a source and drain electrode 42 of the thin film transistor. At least one of the first conductive layer 2 and the second conductive layer 4 is the metal conductive layer 7. For descriptions of specific structure and material of the metal conductive layer 7, contents in the previous embodiment may be referred to, which will not be repeated here.

In some embodiments, both the first conductive layer 2 and the second conductive layer 4 are metal conductive layers, and each metal conductive layer is in a structure of buffer conductive layer/core conductive layer/functional conductive layer.

As a specific example, a three-layer conductive material of the first conductive layer 2 is MoNiTi/Cu/MoNiTi, and a three-layer conductive material of the second conductive layer 4 is MoNiTi/Cu/MoNiTi.

As another specific example, the three-layer conductive material of the first conductive layer 2 is MoNb/Cu/MoNiTi, and the three-layer conductive material of the second conductive layer 4 is MoNiTi/Cu/MoNiTi.

As another specific example, the three-layer conductive material of the first conductive layer 2 is ITO/Cu/MoNiTi, and the three-layer conductive material of the second conductive layer 4 is MoNiTi/Cu/MoNiTi.

As another specific example, the three-layer conductive material of the first conductive layer 2 is MoNiTi/Cu/MoNiTi, and the three-layer conductive material of the second conductive layer 4 is MoNiTi/Cu/MoNiTi.

As another specific example, the three-layer conductive material of the first conductive layer 2 is IZO/Cu/MoNiTi, and the three-layer conductive material of the second conductive layer 4 is MoNiTi/Cu/MoNiTi.

As another specific example, the three-layer conductive material of the first conductive layer 2 is MoNiTi/Cu/MoNiTi, and the three-layer conductive material of the second conductive layer 4 is MoNb/Cu/MoNiTi.

As another specific example, the three-layer conductive material of the first conductive layer 2 is ITO/Cu/MoNiTi, and the three-layer conductive material of the second conductive layer 4 is MoNb/Cu/MoNiTi.

As another specific example, the three-layer conductive material of the first conductive layer 2 is IZO/Cu/MoNiTi, and the three-layer conductive material of the second conductive layer 4 is MoNb/Cu/MoNiTi.

The display substrate is further provided thereon with an active layer. In the case shown in FIG. 3A, the gate 22 of the thin film transistor is located at a side of the active layer close to the base substrate 1, at which time the thin film transistor on the display substrate is a bottom-gate-type thin film transistor. In FIG. 3B, the gate 22 of the thin film transistor is located at a side of the active layer away from the base substrate 1, at which time the thin film transistor on the display substrate is a top-gate-type thin film transistor. It can be seen that technical solutions of the present disclosure may be applied to a display substrate having a bottom-gate-type thin film transistor, and may also be applied to a display substrate having a top-gate-type thin film transistor.

In addition, a material of the active layer may be Amorphous Silicon (α-Si for short), Low Temperature Poly-silicon (LTPS for short), Low Temperature Polycrystalline Oxide (LTPO for short), or the like. A specific material of the active layer is not limited in the technical solutions of the present disclosure.

In addition, the display substrate in the embodiments of the present disclosure may be a display substrate in a Liquid Crystal Display panel, an Organic Light-Emitting Diode panel, or a Quantum Dots panel, which is not limited in the present disclosure.

Based on a same inventive concept, an embodiment of the present disclosure further provides a display panel, which includes: a display substrate and an opposite substrate disposed opposite to the display substrate, wherein the display substrate may be selected as the display substrate provided in any of the previous embodiments.

In some embodiments, the display panel may be an LCD panel, an OLED panel, a QD panel, or the like.

Based on a same inventive concept, an embodiment of the present disclosure further provides a display device, which includes a display panel. The display panel is selected as the display panel provided in any of the previous embodiments, and the display device may further include a driving module configured to drive the display panel for display.

The display device in the embodiments of the present disclosure may specifically be an electronic tag, a tablet computer, a laptop computer, a palmtop computer, a vehicle-mounted electronic device, a Mobile Internet Device (MID for short), an augmented reality (AR for short)/virtual reality (VR for short) device, a robot, a wearable device, an Ultra Mobile Personal Computer (UMPC for short), a netbook, a personal digital assistant (PDA for short), a personal computer (PC for short), a television (TV for short), an electronic photo frame, a navigator, a teller machine, a self-service machine and other display products or components with display functions.

The above description of the embodiments of the present invention has been given for purposes of illustration and description. It is not intended to be exhaustive or to limit the present invention to the precise forms or exemplary embodiments disclosed. Therefore, the previous description should be regarded as illustrative rather than restrictive. Obviously, many modifications and changes will be obvious to those skilled in the art. Embodiments have been selected and described for explaining the principles of the invention and its best mode of practical application, thereby enabling those skilled in the art to understand various embodiments of the present invention and various modifications suitable for the particular use or implementation contemplated. The scope of the present invention is intended to be defined by the appended claims and their equivalents, wherein all terms are intended in their broadest reasonable senses unless otherwise stated. Therefore, the terms “the present invention” and the like do not necessarily limit the scope of the claims to specific embodiments, and references to exemplary embodiments of the present invention do not imply limitations on the present invention, and such limitations should not be inferred. The present invention is limited only by the spirit and the scope of the appended claims. Further, these claims may involve the use of “first,” “second”, or the like, followed by nouns or elements. These terms should be understood as nomenclature and should not be interpreted as limiting a quantity of elements modified by these nomenclatures unless a specific quantity has been given. Any of the advantages and the benefits described may not apply to all embodiments of the present invention. It should be understood that the described embodiments may be modified by those skilled in the art without departing from the scope of the present invention as defined by the appended claims. Furthermore, none of the elements and components in the present disclosure is intended to be made as a contribution to the public, whether or not the elements or the components are explicitly described in the appended claims.

1. A display substrate, comprising:
a base substrate;
a metal conductive layer, located at a side of the base substrate, the metal conductive layer comprising a core conductive layer and a functional conductive layer that are stacked along a direction away from the base substrate;
a material of the core conductive layer comprises: a conductive metal material;
a material of the functional conductive layer comprises: a first diffusion barrier metal material and at least one first adhesion force enhancing metal material, wherein the first diffusion barrier metal material is configured to block diffusion of the conductive metal material, and the at least one first adhesion force enhancing metal material is configured to enhance an adhesion force between the functional conductive layer and a photoresist used in a patterning process of the functional conductive layer;
a surface energy of any of the at least one first adhesion force enhancing metal material is less than or equal to 325 mJ/m², and a range of a sum of atomic percents of all of the at least one first adhesion force enhancing metal material in the functional conductive layer is 5% to 60%.

2. The display substrate of claim 1, wherein the material of the functional conductive layer further comprises: a first oxidation resistance metal material, configured to enhance an oxidation resistance performance of the functional conductive layer; and
a sum of atomic percents of the first oxidation resistance metal materials in the functional conductive layer is 5% to 30%.

3. The display substrate of claim 2, wherein the first oxidation resistance metal material comprises: nickel.

4. The display substrate of claim 1, wherein the at least one first adhesion force enhancing metal material in the functional conductive layer comprises: at least one of aluminum, silver, gold, barium, bismuth, cadmium, cerium, chromium, titanium, gallium, germanium, indium, manganese, neodymium, palladium, platinum, rubidium, antimony, scandium, tin, strontium, yttrium, zinc, and zirconium.

5. The display substrate of claim 1, wherein the first diffusion barrier metal material and the conductive metal material are configured such that they are able to be etched using a same etching liquid.

6. The display substrate of claim 1, wherein the conductive metal material comprises copper; and
the first diffusion barrier metal material comprises molybdenum.

7. The display substrate of claim 1, wherein a range of atomic percents of the first diffusion barrier metal material in the functional conductive layer is 40% to 90%.

8. The display substrate of claim 1, wherein the metal conductive layer further comprises: a buffer conductive layer, located at a side of the core conductive layer away from the functional conductive layer and in contact with the core conductive layer; and
a material of the buffer conductive layer comprises: a second diffusion barrier metal material, configured to block diffusion of the conductive metal material.

9. The display substrate of claim 8, wherein the second diffusion barrier metal material comprises molybdenum.

10. The display substrate of claim 8, wherein the material of the buffer conductive layer further comprises at least one second adhesion force enhancing metal material, configured to enhance an adhesion force between the buffer conductive layer and the core conductive layer.

11. The display substrate of claim 10, wherein a surface energy of any of the at least one second adhesion force enhancing metal material is less than or equal to 325 mJ/m², and a range of a sum of atomic percents of all of the at least one second adhesion force enhancing metal material in the functional conductive layer is 5% to 60%.

12. The display substrate of claim 10, wherein the second adhesion force enhancing metal material in the buffer conductive layer comprises: at least one of aluminum, silver, gold, barium, bismuth, cadmium, cerium, chromium, titanium, gallium, germanium, indium, manganese, neodymium, palladium, platinum, rubidium, antimony, scandium, tin, strontium, yttrium, zinc, and zirconium.

13. The display substrate of claim 8, wherein the material of the buffer conductive layer further comprises: a second oxidation resistance metal material, configured to enhance an oxidation resistance performance of the buffer conductive layer; and
a sum of atomic percents of the second oxidation resistance metal material in the buffer conductive layer is 5% to 30%.

14. The display substrate of claim 13, wherein the first oxidation resistance metal material comprises nickel.

15. The display substrate of claim 8, wherein the second diffusion barrier metal material comprises molybdenum; and
a range of atomic percents of the second diffusion barrier metal material in the buffer conductive layer is 40% to 90%.

16. The display substrate of claim 8, wherein the material of the buffer conductive layer and material of the functional conductive layer are the same; or
a thickness of the buffer conductive layer is 50 Å to 600 Å.

17. (canceled)

18. The display substrate of claim 1, wherein a thickness of the core conductive layer is 1000 Å to 6000 Å; and
a thickness of the functional conductive layer is 50 Å to 600 Å; or
the metal conductive layer comprises a plurality of conductive patterns, and a range of a sidewall slope angle of the conductive patterns is 40° to 50°.

19. (canceled)

20. The display substrate of claim 1, comprising:
a first conductive layer which is located at a side of the base substrate and comprises a gate line;
a first insulation layer located at a side of the first conductive layer away from the base substrate;
a second conductive layer which is located at a side of the first insulation layer away from the base substrate and comprises a data line; and
at least one of the first conductive layer and the second conductive layer is the metal conductive layer.

21. A display panel, comprising: the display substrate of claim 1 and an opposite substrate disposed opposite to the display substrate.

22. A display device, comprising the display panel of claim 21.
